(19) United States
(12) Patent Application Publication
(10) Pub. No.: US 2026/0107518 A1
(43) Pub. Date: Apr. 16, 2026

(54) FERROELECTRIC FIELD-EFFECT TRANSISTOR DEVICE AND METHOD FOR MANUFACTURING THE SAME

(71) Applicant: Taiwan Semiconductor Manufacturing Company, Ltd., Hsinchu (TW)

(72) Inventors: Min-Kun Dai, Hsinchu City (TW); I-Cheng Chang, Hsinchu City (TW); Yen-Chieh Huang, Hsinchu (TW); Yu-Ming Lin, Hsinchu City (TW)

(73) Assignee: Taiwan Semiconductor Manufacturing Company, Ltd., Hsinchu (TW)

(21) Appl. No.: 18/914,269

(22) Filed: Oct. 14, 2024

(51) Int. Cl. H01L 29/78; H01L 21/02; H01L 29/66

(52) U.S. Cl. CPC H10D 30/701; H10D 30/0415; H10P 14/274; H10P 14/6339

(57) ABSTRACT

A method of manufacturing a field-effect transistor device includes forming a bottom electrode, forming a ferroelectric layer over the bottom electrode, forming a seed layer over the ferroelectric layer, forming a channel layer on the seed layer, and forming source/drain electrodes at sidewalls of the channel layer. The seed layer is formed by using a physical vapor deposition (PVD) process, and the seed layer has a quasi-crystalline structure. The channel layer has a spinel structure.

### BACKGROUND

Ferroelectric (FE) memory is a candidate for next generation non-volatile memory benefits due to its fast write/read speed, low power consumption and small size. However, it may be difficult to integrate FE materials with commonly utilized semiconductor device materials and structures while maintaining suitable ferroelectric properties and device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating a method of fabricating a field-effect transistor device in accordance with some embodiments of the present disclosure.

FIGS. 2A through 2E are cross-sectional views of a process for the formation of a field-effect transistor device in accordance with some embodiments of the present disclosure.

FIG. 3 is a plot showing a pulse sequence for an atomic layer deposition (ALD) system that may be used to form a channel layer having a spinel structure in accordance with some embodiments of the present disclosure.

FIG. 4 is a plot showing an alternative pulse sequence for an atomic layer deposition (ALD) system that may be used to form a channel layer having a spinel structure in accordance with some embodiments of the present disclosure.

FIG. 5A illustrates an apparatus for forming a channel layer having a spinel structure in accordance with some embodiments of the present disclosure.

FIG. 5B illustrates a alternative apparatus for forming a channel layer having a spinel structure in accordance with some embodiments of the present disclosure.

FIG. 6 illustrates a seed layer and a crystal structure corresponding to the seed layer in accordance with some embodiments of the present disclosure.

FIG. 7 illustrates an apparatus for forming a seed layer having a spinel structure in accordance with some embodiments of the present disclosure.

FIG. 8 is a plot showing a sputtering sequence for a physical vapor deposition (PVD) system that may be used to form a seed layer having a spinel structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a field-effect transistor device includes a gate electrode, a channel, a gate insulating layer between the gate electrode and the channel, and source/drain electrodes at two sides of the gate electrode. The field-effect transistor device may include a ferroelectric field-effect transistor (FeFET) device. Examples of FeFET include metal-ferroelectric-metal-insulator-semiconductor (MFMIS) FET, double-gate FeFET, GAA FeFET memory, among other examples. In the FeFET device, a ferroelectric (FE) layer is disposed between the gate electrode and a channel layer, and the channel layer may be an amorphous structure. However, amorphous channel layer exhibits higher oxygen vacancy (Vo) and will suffer device reliability. By contrast, at least some embodiments provide a seed layer before the formation of the channel layer according to the method disclosed herein, which can form a channel layer having a spinel/quasi-spinel structure as well as a quasi-crystalline seed layer, thereby reduce Vo and enhance device reliability (e.g. bias temperature instability (BTI), endurance, etc.), as compared to the other approach.

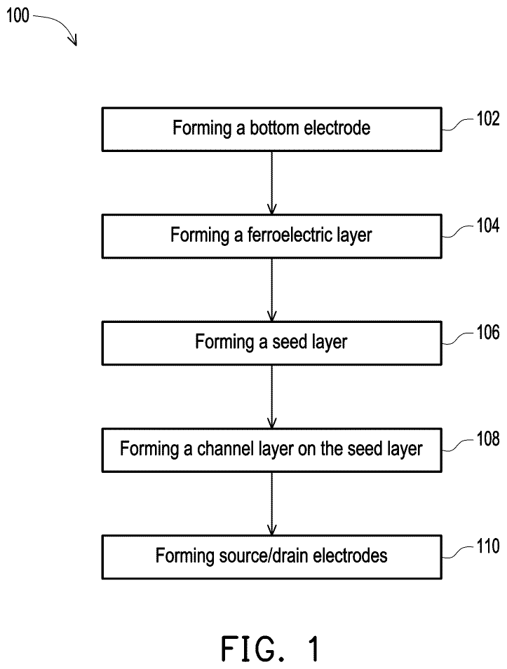

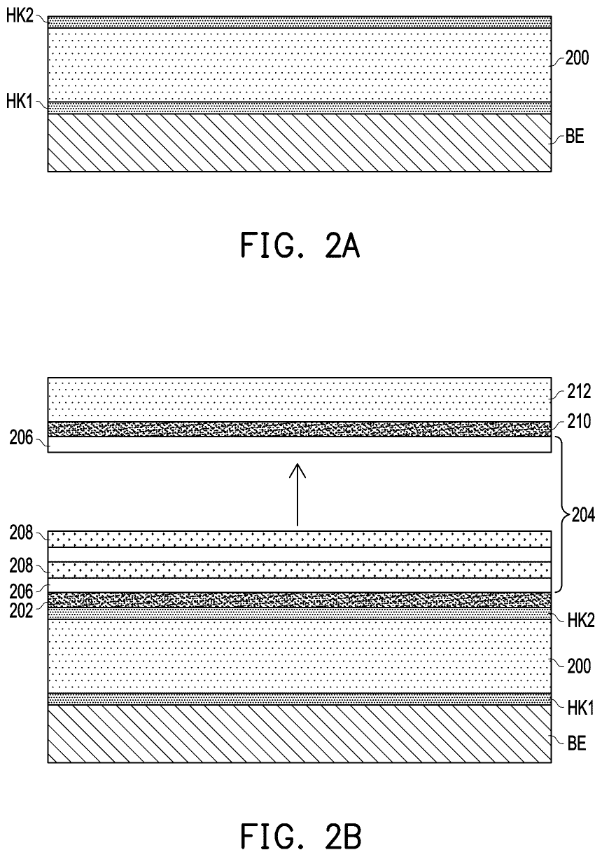

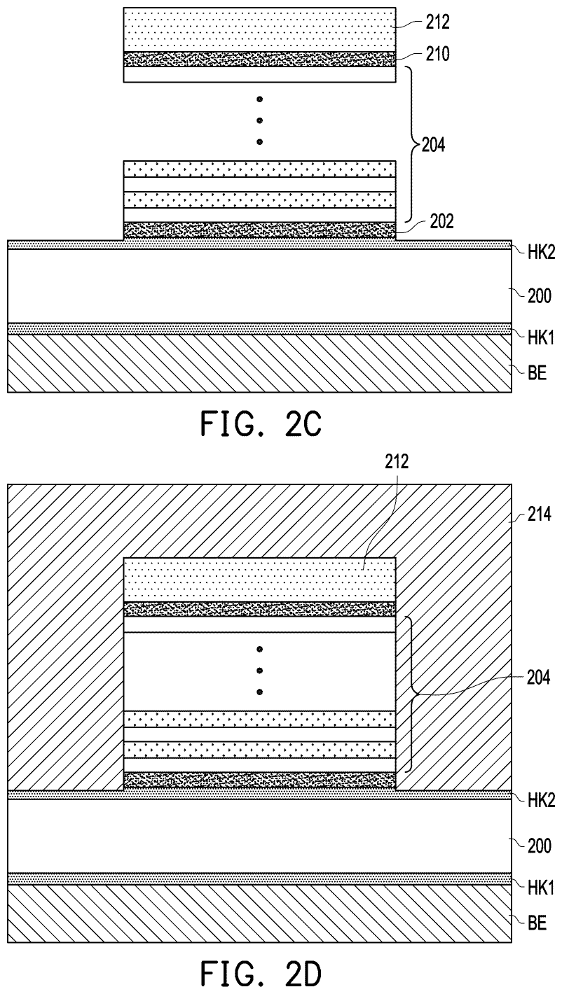

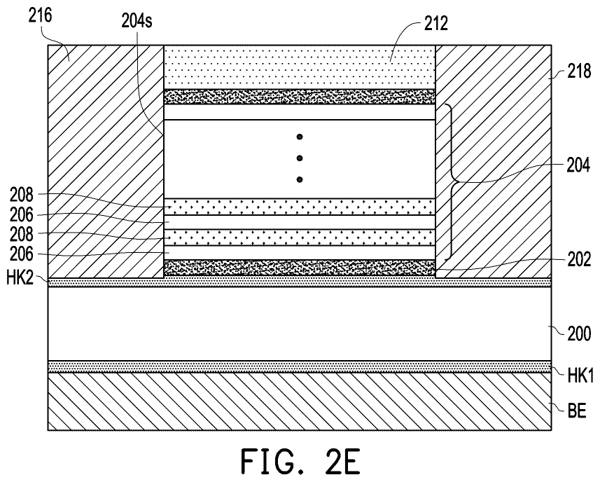

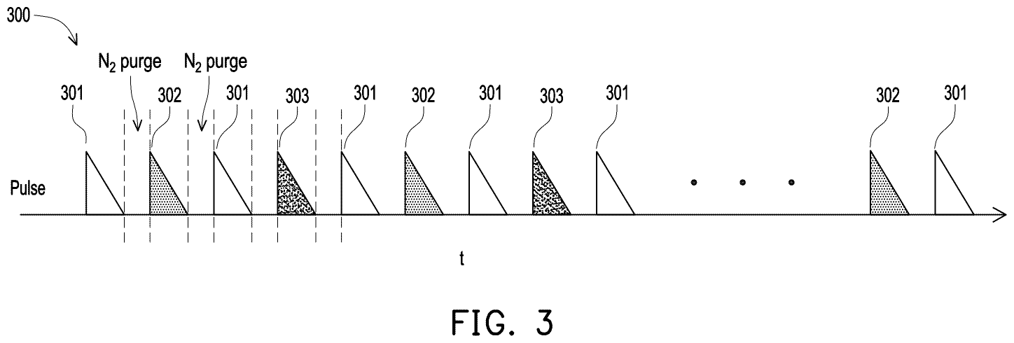

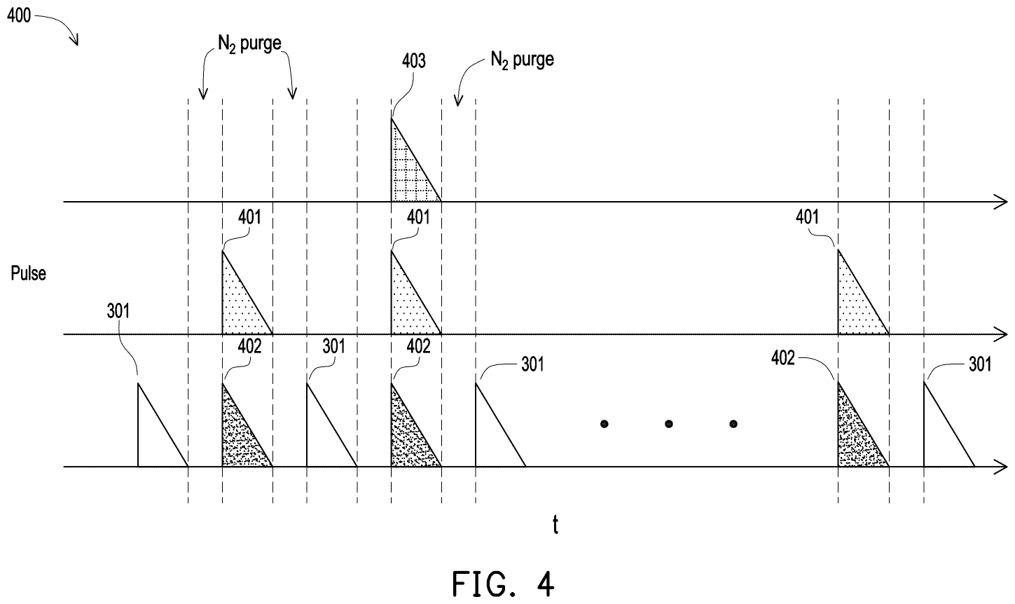

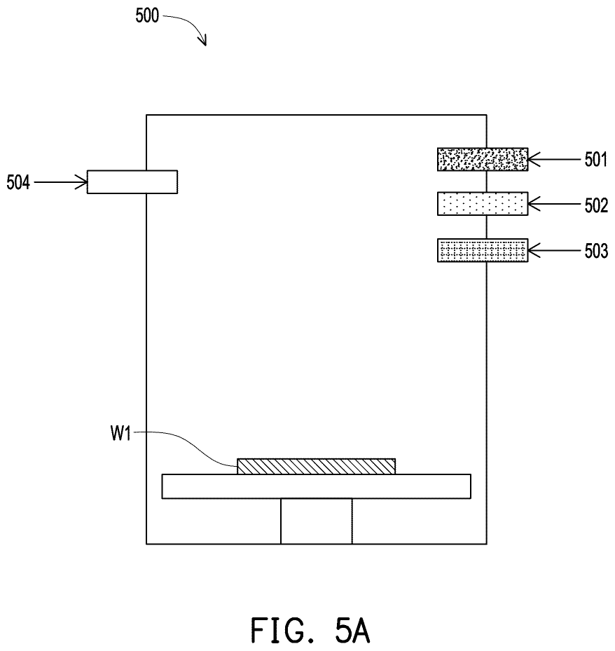

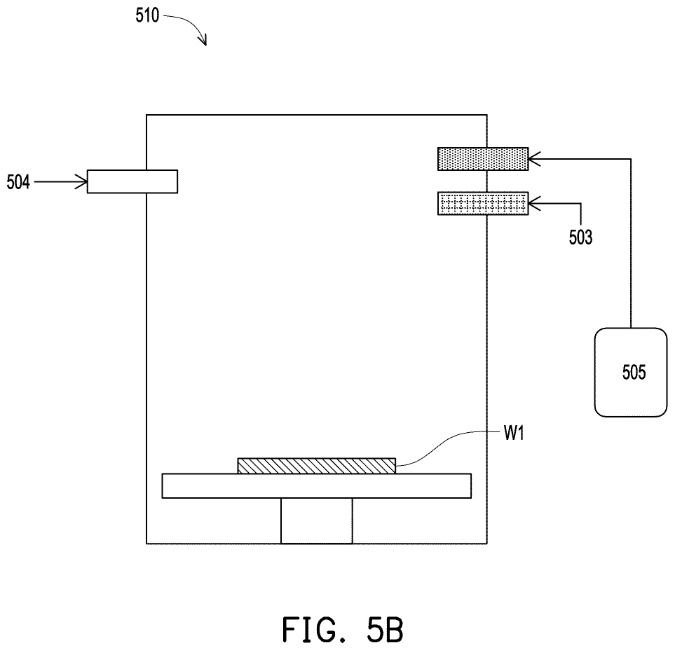

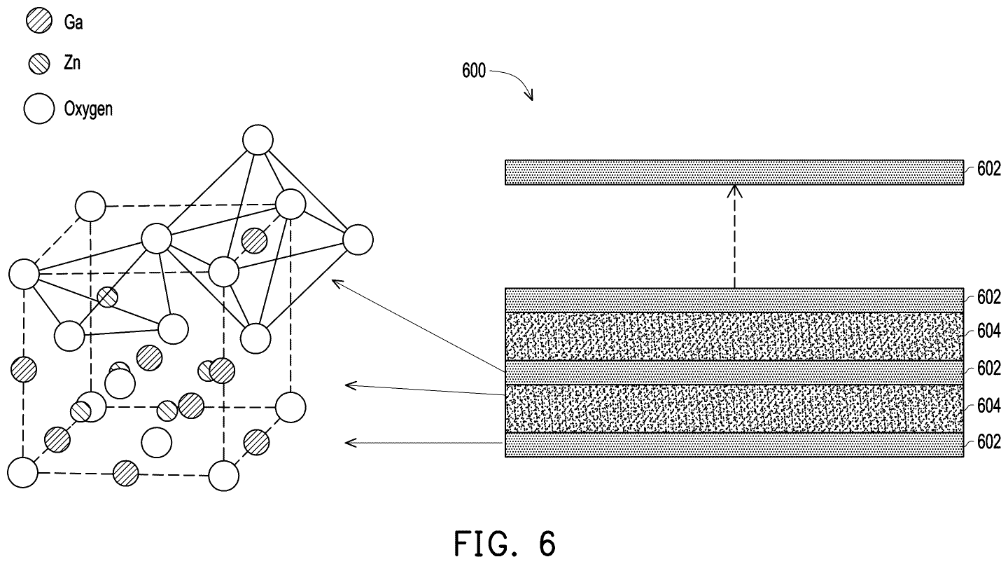

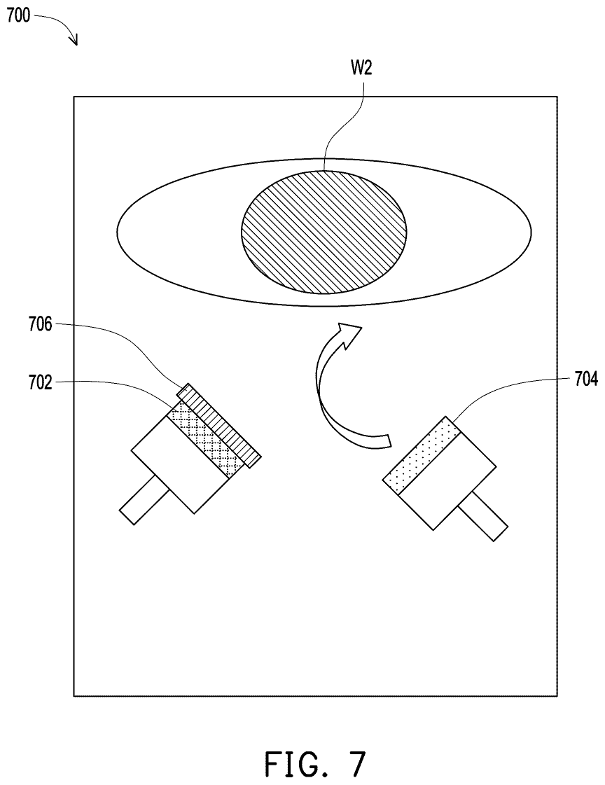

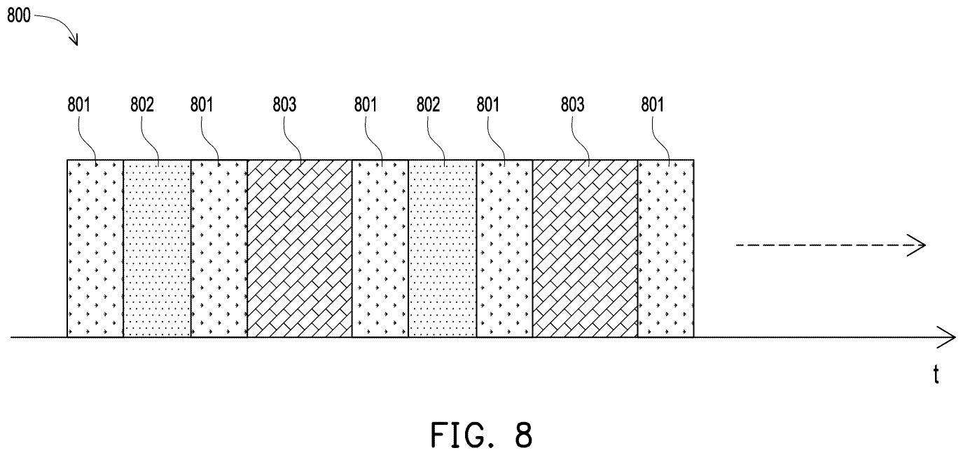

The various aspects of the present disclosure will now be discussed below with reference to FIGS. 1-8. In more detail, FIG. 1 illustrates a flowchart illustrating a method of fabricating a field-effect transistor device according to various aspects of the present disclosure. FIGS. 2A-2E illustrate cross-sectional views of a field-effect transistor device at various stages of fabrication according to embodiments of the present disclosure. FIGS. 3 and 4 are plots showing different pulse sequences for an atomic layer deposition (ALD) system to form a channel layer according to various aspects of the present disclosure. FIGS. 5A and 5B illustrate two apparatuses for forming a channel layer according to various aspects of the present disclosure. FIG. 6 illustrates a seed layer and a crystal structure corresponding to the seed layer according to embodiments of the present disclosure. FIG. 7 illustrates an apparatus for forming a seed layer according to various aspects of the present disclosure. FIG. 8 is a plot showing a sputtering sequence for a physical vapor deposition (PVD) system to form a seed layer according to various aspects of the present disclosure.

Referring now to FIG. 1, a flowchart illustrates a method 100 of fabricating a field-effect transistor device. The method 100 includes a step 102 to forming a bottom electrode. The bottom electrode may be deposited on a dielectric layer or a substrate. The bottom electrode may function as a gate electrode of the field-effect transistor device.

The method 100 includes a step 104 to form a ferroelectric (FE) layer over the bottom electrode.

The method 100 includes a step 106 to form a seed layer over the ferroelectric layer.

The method 100 includes a step 108 to form a channel layer on the seed layer. The seed layer is utilized as seed for forming the channel layer, and the crystal structure of the channel layer is influenced by the seed layer.

The method 100 includes a step 110 to form source/drain electrodes at sidewalls of the channel layer.

In some embodiments, the channel layer is formed using an atomic layer deposition (ALD) process, wherein the channel layer has a spinel structure.

In some embodiments, the seed layer is formed using a physical vapor deposition (PVD) process, wherein the seed layer may be a quasi-crystalline seed layer. In some embodiments, the PVD process includes a pre-deposition thermal treatment before, between and/or after each steps of forming atomic layer.

It is understood that additional steps may be performed before, during, or after the steps 102-110. For example, the method 100 may further include steps of: before the formation of the ferroelectric layer, forming a first high-k dielectric film over an upper surface of the bottom electrode; and after the formation of the ferroelectric layer, forming a second high-k dielectric film over an upper surface of the ferroelectric layer. In other examples, the method 100 may further include a step of: after the formation of the channel layer, forming a capping layer over the channel layer.

The various aspects of the method 100 will now be discussed in more detail with reference to FIGS. 2A-8. For example, FIGS. 2A-2E illustrate diagrammatic fragmentary cross-sectional views of a portion of a field-effect transistor device (in which the field-effect transistor device such as FeFET device is implemented) at various stages of fabrication according to various embodiments of the present disclosure.

Referring now to FIG. 2A, a bottom electrode BE is formed. The bottom electrode BE may be deposited on a dielectric layer or a substrate (not shown). In some embodiments, the bottom electrode BE may be embedded in the dielectric layer. For example, a photoresist layer (not shown) may be deposited over the dielectric layer and patterned using photolithographic techniques. The pattern of the photoresist layer may be transferred to the dielectric layer and thus, the dielectric layer may be patterned to form trenches (not shown). An electrically conductive material may be deposited in the trenches, and a planarization process (e.g., a chemical-mechanical planarization (CMP) process) may be performed to remove excessive conductive material of the bottom electrode BE.

Alternatively, the bottom electrode BE may be deposited as a continuous electrode layer on a dielectric layer or a substrate (not shown), such that the continuous electrode layer contacts an upper surface of the dielectric layer. Selected portions of the continuous electrode may be removed (e.g., by etching the continuous electrode layer through a patterned mask formed using photolithographic processes) to form one or more discrete patterned electrode. Then, additional dielectric material (not shown) may be formed over the exposed surfaces of the dielectric layer, the side surfaces of the patterned electrodes, and optionally over the upper surface of the patterned electrodes to embed the bottom electrode BE within the dielectric material. A planarization process may then be performed to planarize the upper surfaces of the bottom electrode BE and the dielectric layer. In certain embodiments, a top surface of the bottom electrode BE is coplanar with a top surface of the dielectric layer.

The bottom electrode BE may include any suitable electrically conductive material, such as gold (Au), copper (Cu), aluminum (Al), platinum (Pt), tungsten (W), titanium nitride (TiN), zirconium (Zr), titanium (Ti), tantalum (Ta), tantalum nitride (TaN), molybdenum (Mo), ruthenium (Ru), palladium (Pd), cobalt (Co), nickel (Ni), iridium (Ir), iron (Fe), beryllium (Be), chromium (Cr), antimony (Sb), osmium (Os), thorium (Th), vanadium (V), alloys thereof, and combinations of the same. Other suitable materials for the bottom electrode BE are within the contemplated scope of disclosure. The bottom electrode BE may be deposited using any suitable deposition process. For example, suitable deposition processes may include physical vapor deposition (PVD), sputtering, chemical vapor deposition (CVD), atomic layer deposition (ALD), plasma-enhanced chemical vapor deposition (PECVD), or combinations thereof. In some embodiments, the thickness of the bottom electrode BE may be in a range from 50 nm to 10,000 nm, for example, 100 nm to 8,000 nm, or 1,000 nm to 5,000 nm, although lesser and greater thicknesses may also be used.

Referring to FIG. 2A again, a ferroelectric layer 200 is formed over the bottom electrode BE. In some embodiments, before the formation of the ferroelectric layer 200, a first high-k dielectric film HK1 may be formed on the bottom electrode BE. The first high-k dielectric film HK1 may function as a buffer layer for the ferroelectric layer 200 that is subsequently formed over the first high-k dielectric film HK1. Herein, high-k dielectric materials have a dielectric constant greater than 3.9. In some embodiments, the first high-k dielectric film HK1 may be a material having a lattice mismatch with the ferroelectric layer 200 that is subsequently formed over the first high-k dielectric film HK1 such that a tensile strain is induced in the ferroelectric layer 200. It is known that in many ferroelectric materials, such as hafnium zirconium oxide (HZO), small changes in the lattice parameters may result in a larger portion of the ferroelectric material having a desirable crystalline phase, such as an orthorhombic crystal phase. Tensile strain due to lattice mismatch between the first high-k dielectric film HK1 and the ferroelectric layer 200 may provide the ferroelectric layer 200 having improved ferroelectric properties, such as increased remnant polarization, Pr. The first high-k dielectric film HK1 may include a metal oxide material such as HfSiO, HfLaO, Zr-doped HfO₂, Al-doped HfO₂, KNO₃, BiFeO₃, BiMnO₃, YMnO₃, TbMnO₃, PbZr₁₋ₓTiₓO₃, Pb(Zr,Ti)O₃, Pb(Sc_{1/2}Ta_{1/2})O₃, Pb(Sc_{1/2}Nb_{1/2})O₃, Pb(Mg_{1/3}Nb_{2/3})O₃, Pb(Zn_{1/3}Nb_{2/3})O₃, LiTaO₃, LiNbO₃, Sr_{0.8}Bi_{2.2}Ta₂O₉, SrBi₂Nb₂O₉, PbTiO₃, BaTiO₃, SrTiO₃, LiTiO₃, LiNbO₃, BeFeO₃, KNbO₃, KTaO₃, CaTiO₃, GdFeO₃, DyScO₃, Bi₂O₂ staking, Bi₂WO₆, SrBi₂Ta₂O₉, Bi₄Ti₃O₁₂, SrBi₂Ta₂O₉, Mn₃TeO₆, Pb₅Ge₃O₁₁, Gd₂(MoO4)₃, R₃Sb₅O₁₂ (R represents Nd, Sm, Gd, or Yb), LiNaGe₄O₉, BaAl₂O₄, Li₂Ge₇O₁₅, KNO₃, YMnO₃, BaBiO₃, LuFe₂O₄, YFe₂O₄, Fe₂BO₄, La_{1.5}Sr_{0.5}NiO₄, Ta₂O₅, K₂O, Rb₂O, SrO, BaO, a-V₂O₃, a-Cr₂O₃, a-Ga₂O₃, a-Fe₂O₃, a-Ti₂O₃, a-In₂O₃, YAlO₃, Bi₂O₃, Yb₂O₃, Dy₂O₃, Gd₂O₃, SrTiO₃, DyScO₃, TbScO₃, GdScO₃, NdScO₃, NdGaO₃, LaSrAlTaO₃ (LSAT), or a combination thereof. Other suitable materials for the first high-k dielectric film HK1 are within the contemplated scope of disclosure. The first high-k dielectric film HK1 may be deposited using any suitable deposition process. In various embodiments, the first high-k dielectric film HK1 may be deposited using atomic layer deposition (ALD) or pulsed laser deposition (PLD). In some embodiments, the thickness of the first high-k dielectric film HK1 may be in a range from 1 nm to 1000 nm, for example, 10 nm to 800 nm, or 20 nm to 500 nm, although lesser and greater thicknesses may also be used.

In FIG. 2A, the ferroelectric layer 200 is formed over the bottom electrode BE. In embodiments in which the first high-k dielectric film HK1 is present, the ferroelectric layer 200 may be deposited over the upper surface of the first high-k dielectric film HK1. The ferroelectric layer 200 may be formed of any suitable ferroelectric material. In various embodiments, the ferroelectric layer 200 may be hafnium oxide-based ferroelectric material, such as Zr-doped HfO₂, Al-doped HfO₂, HfO₂, HfSiO, HfLaO, etc. Other suitable materials for the ferroelectric layer 200 are within the contemplated scope of disclosure, including, without limitation, KNO₃, BiFeO₃, BiMnO₃, YMnO₃, TbMnO₃, PbZr₁₋ₓTiₓO₃, Pb(Zr,Ti)O₃, Pb(Sc_{1/2}Ta_{1/2})O₃, Pb(Sc_{1/2}Nb_{1/2})O₃, Pb(Mg_{1/3}Nb_{2/3})O₃, Pb(Zn_{1/3}Nb_{2/3})O₃, LiTaO₃, LiNbO₃, Sr_{0.8}Bi_{2.2}Ta₂O₉, SrBi₂Nb₂O₉, PbTiO₃, BaTiO₃, SrTiO₃, LiTiO₃, LiNbO₃, BeFeO₃, KNbO₃, KTaO₃, CaTiO₃, GdFeO₃, DyScO₃, Bi₂O₂ staking, Bi₂WO₆, SrBi₂Ta₂O₉, Bi₄Ti₃O₁₂, SrBi₂Ta₂O₉, Mn₃TeO₆, Pb₅Ge₃O₁₁, Gd₂(MoO4)₃, R₃Sb₅O₁₂ (R represents Nd, Sm, Gd, or Yb), LiNaGe₄O₉, BaAl₂O₄, Li₂Ge₇O₁₅, KNO₃, YMnO₃, SmB₆, BaBiO₃, LuFe₂O₄, YFe₂O₄, Fe₂BO₄, La_{1.5}Sr_{0.5}NiO₄, and combinations thereof. In embodiments, the ferroelectric layer 200 may include a single layer of ferroelectric material, or multiple layers of ferroelectric materials which may have different compositions. In various embodiments, the ferroelectric layer 200 may have a crystal structure including cubic, tetragonal and/or orthorhombic crystal phases. The ferroelectric layer 200 may be deposited using any suitable deposition process. In various embodiments, the ferroelectric layer 200 may be deposited using atomic layer deposition (ALD). In some embodiments, the thickness of the ferroelectric layer 200 may be in a range from 1 nm to 1000 nm, for example, 10 nm to 800 nm, or 20 nm to 500 nm, although lesser and greater thicknesses may also be used.

In some embodiments, after the formation of the ferroelectric layer 200, a second high-k dielectric film HK2 may be formed on the ferroelectric layer 200. The second high-k dielectric film HK2 may function as a barrier between the ferroelectric layer 200 and a seed layer that may be subsequently formed over the second high-k dielectric film HK2. The second high-k dielectric film HK2 may help to reduce surface state density (Dit) and inhibit carrier (i.e., electron and/or hole) injection from a channel layer (not shown). In various embodiments, the material of the second high-k dielectric film HK2 may have a higher band gap (Eg) than the band gap of the subsequently-formed seed/channel layer. The second high-k dielectric film HK2 and the first high-k dielectric film HK1 may be formed by similar method through ALD, CVD, or the like. In some embodiments, the second high-k dielectric film HK2 and the first high-k dielectric film HK1 are made of different materials. In some alternative embodiments, the second high-k dielectric film HK2 and the first high-k dielectric film HK1 are made of the same material. In some embodiments, the thickness of the second high-k dielectric film HK2 may be in a range from 1 nm to 1000 nm, for example, 10 nm to 800 nm, or 20 nm to 500 nm, although lesser and greater thicknesses may also be used.

Referring now to FIG. 2B, a seed layer 202 is formed over the ferroelectric layer 200. In embodiments in which the second high-k dielectric film HK2 is present, the seed layer 202 may be deposited over the upper surface of the second high-k dielectric film HK2. In various embodiments, the seed layer 202 may include materials which is contribute to form a spinel/quasi-spinel structure thereon, wherein the materials for the seed layer 202 are within the contemplated scope of disclosure, including, without limitation, ZnGa₂O₄, MgO, Al₂O₃, MgAlOx, MgZn₂O₄, etc. In some embodiments, the seed layer 202 may be deposited using physical vapor deposition (PVD). In some embodiments, the thickness of the seed layer 202 may be in a range from 1 nm to 50 nm, for example, 1 nm to 20 nm, or 1 nm to 10 nm, although lesser and greater thicknesses may also be used.

Referring to FIG. 2B again, a channel layer 204 formed on the seed layer 202. The channel layer 204 may be formed with one or more semiconductor materials having a conductive type of semiconductor (e.g., an n-type semiconductor having electrons as a majority carrier or a p-type semiconductor having holes as a majority carrier). In some embodiments, the one or more semiconductor materials may comprise one or more n-type semiconductors, such as cadmium indium sulfide (CdIn₂S₄), indium gallium zinc oxide (IGZO), gallium zinc oxide (GaZnO), HgCr₂Se₄, magnesium titanium oxide (Mg₂TiO₄), LiGa₅O₈, Cobalt-aluminate spinel (CoAl₂O₄), spinel zinc cobalt oxide (ZnCo₂O₄), zinc gallate (ZnGa₂O₄), zinc aluminate (ZnAl₂O₄), zinc indate (ZnIn₂O₄), spinel ferrites (MFe₂O₄, where M represents Mg, Co, Ni, Zn, Fe, Mn, Cu, etc.), cadmium-tin oxide (Cd₂SnO₄), cobalt chromate (CoCr₂O₄), or the like. In some embodiments, the one or more oxide semiconductor materials may comprise one or more p-type oxide semiconductors, such as NiCrₓFe₂₋ₓO₄ spinel (0≤x≤0.6), spinel zinc gallate (ZnGa₂O₄), NiFe₂O₄, ZnCo₂O₄, ZnIr₂O₄, Ni_{0.99}Co_{0.01}Mn_{0.02}Fe_{1.98}O_{4-δ} (δ=0−3), Li_{0.5}Sm_{0.1}Fe_{2.4}O₄, Mg_{0.9}Sn_{0.1}Fe₂O₄, Fe₃O₄—Fe₂TiO₄, Al-doped nickel oxide (Al:NiOx), or the like. In some embodiments, the thickness of the channel layer 204 may be in a range from 1 nm to 500 nm, from 1 nm to 200 nm, or from 1 nm to 100 nm, although lesser and greater thicknesses may also be used.

In FIG. 2B, the channel layer 204 is formed, and the channel layer 204 has a spinel structure. In some embodiments, the channel layer 204 is formed by using an atomic layer deposition (ALD) process. In various embodiments, deposition of channel layer 204 directly onto the second high-k dielectric layer HK2 or the ferroelectric layer 200 (i.e., in embodiments in which the seed layer 202 is not present) may result in the formation of amorphous channel layer due to lattice mismatch between the channel layer 204 and the underlying layer. In some embodiments, the channel layer 204 may be formed by depositing a series of sub-layers over the upper surface of the seed layer 202, and the sub-layers may have different materials for forming quasi-spinel structure. In some embodiments, the channel layer 204 comprises a plurality of first sublayers 206 and a plurality of second sublayers 208 alternately stacked. In some embodiments, the first sublayers 206 may be formed by reacting a first precursor mixture with a third precursor mixture, wherein the first precursor mixture may include at least one cation in the spinel structure, and the third precursor mixture may include an anion in the spinel structure. In some embodiments, the second sublayers 208 may be formed by reacting a second precursor mixture with the third precursor mixture, wherein the second precursor mixture may include all cations or some cations in the spinel structure. In some embodiments, the second precursor mixture comprises the same precursors as the first precursor mixture.

FIG. 3 is a plot showing a pulse sequence 300 for an atomic layer deposition (ALD) system that may be used to form the channel layer 204 made from a plurality of first sublayers 206 and a plurality of second sublayers 208 in accordance with some embodiments of the present disclosure.

Referring to FIG. 3, the sequence 300 of ALD precursor pulses introduced into the ALD reaction chamber is schematically illustrated over time, t. A first pulse 301 may be the third precursor mixture including precursors containing an anion in the spinel structure of the channel layer 204. In case of the channel layer 204 being quasi-spinel IGZO thin film, the third precursor mixture of the first pulse 301 may be an oxygen precursor (e.g. O₂, O₃, or H₂O), and the pulse time of the first pulse 301 is, for example, in a range of from 0.1 s (second) to 10 s, although longer or shorter time may also be used. A second pulse 302 may be the first precursor mixture including precursors containing metal(s) of the first sublayer 206 of the channel layer 204. The metal(s) in the first precursor mixture may react with the oxygen precursor from the first pulse 301 so as to from the first sublayer 206 of the channel layer 204. In case of the channel layer 204 being quasi-spinel IGZO thin film, the first precursor mixture of the second pulse 302 may be a precursor mixture containing indium (In) and gallium (Ga), and the pulse time of the second pulse 302 is, for example, in a range of from 0.1 s to 10 s, although longer or shorter time may also be used. In one non-limiting example, the precursor source of In-containing precursor may be indium(III) acetate (C₆H₉InO₆), indium(III) acetate hydrate (C₆H₉InO₆·xH₂O), or indium(III) acetylacetonate (C₁₅H₂₁InO₆). In one non-limiting example, the precursor source of Ga-containing precursor may be triethylgallium ((CH₃CH₂)₃Ga), trimethylgallium (Ga(CH₃)₃), or Tris(dimethylamido)gallium(III) (C₁₂H₃₆Ga₂N₆). A third pulse 303 may be the second precursor mixture including precursors containing metal(s) of the second sublayer 208 of the channel layer 204. The metal(s) in the second precursor mixture may react with the oxygen precursor from the first pulse 301 so as to from the second sublayer 208 of the channel layer 204. In case of the channel layer 204 being quasi-spinel IGZO thin film, the second precursor mixture of the third pulse 303 may be a precursor mixture containing In, Ga and zinc (Zn), and the pulse time of the third pulse 303 is, for example, in a range of from 0.1 s to 10 s, although longer or shorter time may also be used. In one non-limiting example, the precursor source of Zn-containing precursor may be bis(pentafluorophenyl)zinc ((C₆F₅)₂Zn), bis(2,2,6,6-tetramethyl-3,5-heptanedionato)zinc(II) (Zn(OCC(CH₃)₃CHCO—C(CH₃)₃)₂), diethylzinc ((C₂H₅)₂Zn), diphenylzinc ((C₆H₅)₂Zn), or Zinc shot. Other suitable precursors are within the contemplated scope of disclosure. In various embodiments, there is an N₂ purge among different pulses, and the time of the N₂ purge is, for example, in a range of from 0.1 s to 5 s, although longer or shorter time may also be used. In other words, one N₂ purge may be between the first pulse 301 and the second pulse 302, and one N₂ purge may be between the first pulse 301 and the third pulse 303, and so on.

In case of the channel layer 204 being quasi-spinel IGZO thin film, the first sublayers 206 may include a combination of indium oxide (InOx) and gallium oxide (GaOx), and the second sublayer 208 may include a mixing of InOx, GaOx, and zinc oxide (ZnOx). Since crystalline IGZO with c-axis orientation without seldom crystal grain boundaries, the crystalline structure of IGZO is utilized as channel layer to increase mobility of the field-effect transistor device.

FIG. 4 is a plot showing an alternative pulse sequence 400 for an ALD system that may be used to form the channel layer 204 made from a plurality of first sublayers 206 and a plurality of second sublayers 208 in accordance with some embodiments of the present disclosure.

Referring to FIG. 4, the pulse sequence 400 in this embodiment is similar to the pulse sequence 300 shown in FIG. 3, except that instead of introducing a single pulse (i.e. the second pulse 302 or the third pulse 303), the ALD system may be operated in a co-pulse mode. For example, the second pulse 302 in FIG. 3 may be replaced by a first precursor pulse 401 and a second precursor pulse 402 which are introduced into the ALD reaction chamber at the same time. The first precursor pulse 401 may include a precursor containing a first metal, and the second precursor pulse 402 may include a precursor containing a second metal. In case of the channel layer 204 being quasi-spinel IGZO thin film, the first precursor pulse 401 may include a precursor containing gallium (Ga), and the second precursor pulse 402 may include a precursor containing indium (In), and the pulse time of the first precursor pulse 401/the second precursor pulse 402 is, for example, in a range of from 0.1 s to 10 s, although longer or shorter time may also be used. In addition, the third pulse 303 in FIG. 3 may be replaced by the first precursor pulse 401, a second precursor pulse 402 and a third precursor pulse 403 which are introduced into the ALD reaction chamber at the same time. The third precursor pulse 403 may include a precursor containing a third metal. In case of the channel layer 204 being quasi-spinel IGZO thin film, the first precursor pulse 401 may include a precursor containing Ga, the second precursor pulse 402 may include a precursor containing In, and the third precursor pulse 403 may include a precursor containing zinc (Zn). The respective precursors may mix within the ALD reaction chamber and react with the third precursor mixture of the first pulse 301 such as an oxygen precursor (e.g. O₂, O₃, or H₂O) to form the plurality of first sublayers 206 and the plurality of second sublayers 208 over time, t.

FIG. 5A illustrates an apparatus for forming the channel layer 204 having a spinel structure in accordance with some embodiments of the present disclosure. In FIG. 5A, the apparatus 500 may be an ALD chamber or a pulsed laser deposition (PLD) chamber, and a wafer W1 is placed in the chamber. The apparatus 500 is suitable for co-pulsing method to form the channel layer 204 in the wafer W1 in accordance with some embodiments of the present disclosure. In FIG. 5A, a first precursor 501, a second precursor 502, a third precursor 503, and a fourth precursor 504 are respectively applied to the chamber, and thus it is possible to accomplish the co-pulsing method as the pulse sequence 400 of FIG. 4. In case of the channel layer 204 being IGZO thin film, the first precursor 501 may include a precursor containing indium (In), the second precursor 502 may include a precursor containing gallium (Ga), the third precursor 503 may include a precursor containing zinc (Zn), and the fourth precursor 504 may include a precursor containing oxygen (O).

FIG. 5B illustrates a alternative apparatus for forming the channel layer 204 having a spinel structure in accordance with some embodiments of the present disclosure. The apparatus 510 in this embodiment is similar to the apparatus 500 shown in FIG. 5A, except that the first precursor 501 and the second precursor 502 are replaced by a precursor mixture 505. In case of the channel layer 204 being IGZO thin film, the precursor mixture 505 may include a mixing of In/Ga precursors. In other embodiments, two precursor mixtures may be utilized in which one being a mixing of In/Ga precursors and the other being a mixing of In/Ga/Zn precursors.

Referring to FIG. 2B again, a final sublayer 210 may be formed on the channel layer 204. In some embodiments, the final sublayer 210 may be formed on an upper surface of topmost first sublayer 206 of the channel layer 204. In some embodiments, the final sublayer 210 has a material the same as the materials for the seed layer 202. In various embodiments, the final sublayer 210 may be deposited using a physical vapor deposition (PVD) process or a pulsed laser deposition (PLD) process. In some embodiments, the final sublayer 210 has same composition as the seed layer 202. In the presence of the final sublayer 210, the surface defects in the channel layer 204 may be reduced. In various embodiments, the final sublayer 210 may have a relatively high bonding energy. In some embodiments, the channel layer 204 including the alternating stack of first/second sublayers 206, 208 and the final sublayer 210, may have a total thickness between 1 and 500 nm (e.g., between 1 nm and 200 nm, or between 1 nm and 100 nm), although greater or lesser thicknesses may be used. After the formation of the final sublayer 210, a capping layer 21 may be deposited on the upper surface of the final sublayer 210. The capping layer 212 may be composed of a suitable dielectric material, such as aluminum oxide (AlOx) or silicon oxide (SiOx). Other materials are within the contemplated scope of disclosure. In some embodiments, the capping layer 212 may be a low-k dielectric material. The capping layer 212 may be deposited using any suitable deposition method, such as physical vapor deposition (PVD), sputtering, chemical vapor deposition (CVD), atomic layer deposition (ALD), plasma-enhanced chemical vapor deposition (PECVD), or combinations thereof.

Referring to FIG. 2C, in order to form source/drain electrodes, the channel layer 204 and the seed layer 202 may be patterned. In some embodiments, a photoresist layer (not shown) may be deposited over the capping layer 212 and patterned using photolithographic techniques. The pattern of the photoresist layer may be transferred to the capping layer 212 and thus, the channel layer 204 (including the final sublayer 210) is exposed. Next, selected portions of the channel layer 204 and the seed layer 202 may be removed by etching through the patterned capping layer 212 to form a patterned channel layer 204. In some embodiments, an upper portion of the second high-k dielectric film HK2 may be removed. In other words, the second high-k dielectric film HK2 has exposed portion, and the thickness of the exposed portion is thinner than that of the portion under the patterned channel layer 204. In some alternative embodiments, the etching for removing the selected portions of the channel layer 204 and the seed layer 202 is performed by using the second high-k dielectric film HK2 as an etching stop layer. Accordingly, the thickness of the second high-k dielectric film HK2 is substantially uniform throughout the layer.

Referring to FIG. 2D, an electrically conductive material 214 may be deposited over the channel layer 204 to cover the capping layer 212 and the second high-k dielectric film HK2. In various embodiments, the electrically conductive material 214 may include any suitable electrically conductive material, such as molybdenum (Mo), copper (Cu), aluminum (Al), zirconium (Zr), titanium (Ti), tungsten (W), tantalum (Ta), ruthenium (Ru), palladium (Pd), platinum (Pt), cobalt (Co), nickel (Ni), iridium (Ir), iron (Fe), beryllium (Be), chromium (Cr), antimony (Sb), osmium (Os), thorium (Th), vanadium (V), selenium (Se), gold (Au), carbon (C), rhodium (Rh), rhenium (Re), tellurium (Te), mercury (Hg), tin (Sn), zinc (Zn), niobium (Nb), silver (Ag), lead (Pb), bismuth (Bi), cadmium (Cd), gallium (Ga), indium (In), manganese (Mn), hafnium (Hf), thallium (Tl), arsenic (As), magnesium (Mg), uranium (U), lanthanum (La), scandium (Sc), lutetium (Lu), neodymium (Nd), gadolinium (Gd), yttrium (Y), terbium (Tb), lithium (Li), cerium (Ce), calcium (Ca), sodium (Na), samarium (Sm), barium (Ba), strontium (Sr), europium (Eu), potassium (K), rubidium (Rb), cesium (Cs), alloys thereof, and combinations of the same. Other suitable electrode materials are within the scope of disclosure. The electrically conductive material 214 may be deposited using any suitable deposition method, such as physical vapor deposition (PVD), sputtering, chemical vapor deposition (CVD), atomic layer deposition (ALD), plasma-enhanced chemical vapor deposition (PECVD), or combinations thereof.

Referring to FIG. 2E, a planarization process, such as a chemical mechanical planarization (CMP) process, may be used to remove portions of the electrically conductive material 214 from above the upper surfaces of the capping layer 212 and provide discrete source/drain electrodes 216 and 218 at sidewalls 204s of the channel layer 204. Therefore, the capping layer 212 may function as a stop layer for the planarization process. In some embodiments, the upper surfaces of the source/drain electrodes 216 and 218 may be co-planar with the upper surfaces of the capping layer 212. In some embodiments, the source/drain electrodes 216 and 218 may be in direct contact with the sidewalls 204s of the channel layer 204. In some embodiments, the thickness of the source/drain electrodes 216 and 218 may be in a range from 20 nm to 100 μm, for example, from 100 nm to 80 μm, or from 1 μm to 50 μm, although lesser and greater thicknesses may also be used.

In FIG. 2E, a field-effect transistor device is provided. The field-effect transistor device includes at least a bottom electrode BE, a ferroelectric layer 200 formed over the bottom electrode BE, a quasi-crystalline seed layer 202 formed over the ferroelectric layer 200, a channel layer 204 formed on the quasi-crystalline seed layer 202, and source/drain electrodes 216 and 218 disposed at two sides of the channel layer 104 over the ferroelectric layer 200, wherein the channel layer 204 has a spinel structure. In some embodiments, the bottom electrode BE may have a length of 30-10,000 nm and a width of 100-10,000 nm, but it is not limited thereto. In some embodiments, the seed layer 202 comprises a plurality of first atomic layers and a plurality of second atomic layers alternately stacked. In some embodiments, a thickness of the seed layer 202 is in a range of 1-50 nm. In some embodiments, the channel layer 204 comprises a plurality of first sublayers 206 and a plurality of second sublayers 208 alternately stacked. In some embodiments, the channel layer 204 may have a channel length of 3-1,000 nm and a channel width of 100-10,000 nm, but it is not limited thereto. In some embodiments, the source/drain electrodes 216 and 218 are in direct contact with the two sides of the channel layer 204. In further embodiments, a first high-k dielectric layer HK1 is disposed between the bottom electrode BE and the ferroelectric layer 200, and a second high-k dielectric layer HK2 is disposed between the quasi-crystalline seed layer 202 and the ferroelectric layer 200.

FIG. 6 illustrates a seed layer and a crystal structure corresponding to the seed layer in accordance with some embodiments of the present disclosure. In FIG. 6, the seed layer 600 over a ferroelectric layer (not shown) is formed using a physical vapor deposition (PVD) process, wherein the seed layer 600 has a spinel structure. In some embodiments, the power of the PVD process may be in a range from 1000 W to 1500 W. In some embodiments, the pressure of the PVD process may be less than 1 mtorr. In some embodiments, the temperature of the PVD process may be in a range from 100° C. to 400° C. In some embodiments, the O₂/(O₂+Ar) of the PVD process may be in a range from 10% to 80%. In some embodiments, the seed layer 600 includes a plurality of first atomic layers 602 and a plurality of second atomic layers 604 alternately stacked. The term “atomic layer” refers to a thin film having a extremely thin thickness, such as the thickness of one or several atoms. The first atomic layer 602 may be deposited first, and then the second atomic layer 604 may be formed by a co-sputtering or a deposition step using a mixing target. The materials for the seed layer 600 are within the contemplated scope of disclosure, including, without limitation, ZnGa₂O₄, MgO, Al₂O₃, MgAlOx, MgZn₂O₄, etc. In some embodiments, the thickness of the seed layer 600 may be in a range from 1 nm to 50 nm, for example, 1 nm to 20 nm, or 1 nm to 10 nm, although lesser and greater thicknesses may also be used. The seed layer 600 may replace the seed layer 202 in FIG. 2B to form on the upper surface of the second high-k dielectric film HK2. In case of the seed layer 600 being quasi-crystalline spinel ZnGa₂O₄, the first atomic layer 602 may correspond to the lower portion of the spinel crystal structure containing oxygen atoms and gallium atoms, and the second atomic layer 604 may correspond to the middle portion of the spinel crystal structure containing zinc atoms, gallium atoms and oxygen atoms. Therefore, the deposition sequence of the first atomic layers 602 and the second atomic layers 604 can switch amorphous to spinel and is beneficial to the formation of a quasi-crystalline spinel structure. In some embodiments, the seed layer 600 may have (222) crystallographic texture for forming spinel IGZO.

FIG. 7 illustrates an apparatus for forming the seed layer 600 in accordance with some embodiments of the present disclosure.

In FIG. 7, the apparatus 700 may be a PVD chamber, and a wafer W2 is placed in the PVD chamber. In some embodiments, a first target 702, a second target 704 and a shutter 706 are disposed in the chamber. In case of the seed layer 600 being quasi-crystalline spinel ZnGa₂O₄, the first target 702 may be a zinc oxide (ZnO) target, and the second target 704 may be a gallium oxide (GaO) target. The shutter 706 may be open or close according to different deposition stages. The sputtering sequence may be shown in FIG. 8.

Referring to FIG. 7 and FIG. 8, a sequence 800 of PVD deposition is schematically illustrated over time, t. The sequence 800 includes at least a pre-heat stage 801, a first layer deposition stage 802, and a second layer deposition stage 803. For example, a pre-deposition thermal treatment is first performed at the pre-heat stage 801, and the shutter 706 is open at the same time. In some embodiments, the temperature of the pre-deposition thermal treatment may be in a range from 150° C. to 400° C., and the time of the pre-deposition thermal treatment is less than 30 s or less than 10 s, although longer or shorter time may also be used. Next, the shutter 706 is close to block the first target 702, and in the first layer deposition stage 802, the second target 704 is bombarded by energetic ions, such as a plasma, causing gallium oxide to be knocked off the second target 704 and deposited as the first atomic layer on a ferroelectric layer or a high-k dielectric layer (not shown) over the wafer W2. In some embodiments, the time of the first layer deposition stage 802 is in a range from 0.1 s to 10 s, although longer or shorter time may also be used. After that, another pre-deposition thermal treatment is performed while the shutter 706 is open again at the second pre-heat stage 801. In some embodiments, each pre-deposition thermal treatments in the sputtering sequence 800 has the same process parameters (e.g. temperature and process time). In some embodiments, those pre-deposition thermal treatments in the sputtering sequence 800 have different process parameters. After the pre-deposition thermal treatment, in the second layer deposition stage 803, the first target 702 and the second target 704 are bombarded by energetic ions together, causing gallium oxide and zinc oxide to be knocked off the first target 702 and the second target 704 and then co-sputtered as the second atomic layer on the first atomic layer. In some embodiments, the time of the second layer deposition stage 803 is in a range from 0.1 s to 30 s, although longer or shorter time may also be used. Above steps are repeated several times to finish the seed layer 600. Since the pre-deposition thermal treatment is in-situ between each of the first layer deposition stages 802 and each of the second layer deposition stages 803, the pre-deposited atomic layer may be crystallized at that time, thereby forming the seed layer having a quasi-crystalline spinel structure. In various embodiments, without the pre-deposition thermal treatment, the PVD process may result in high anneal temperature (>700° C.) for forming the seed layer. By contrast, in the embodiments with the pre-deposition thermal treatment, there is no need to do the high anneal temperature, and thus the high anneal temperature can be omitted to accomplish low thermal budget.

In alternative embodiments, the target in the apparatus 700 may be a mixing target; for instance, the first target 702 may be a mixing target of gallium oxide (GaO) and zinc oxide (ZnO), wherein a ratio of GaO to ZnO of the mixing target may be approximately 2:1 to meet the ideal composition ratio of the deposited layer. Except for the detail of the second layer deposition stage, the sputtering sequence is the same as described above. During the second layer deposition stage 803, the shutter 706 is close to block the second target 704, and the mixing target (i.e. the first target 702) is bombarded by energetic ions causing gallium oxide and zinc oxide to be knocked off the first target 702 and deposited as the second atomic layer on the first atomic layer.

According to some embodiments, a method of manufacturing a field-effect transistor device includes forming a bottom electrode, forming a ferroelectric layer over the bottom electrode, forming a quasi-crystalline seed layer over the ferroelectric layer, forming a channel layer on the quasi-crystalline seed layer, and forming source/drain electrodes at sidewalls of the channel layer. The channel layer is formed, and the channel layer has a spinel structure.

According to some embodiments, a method of manufacturing a field-effect transistor device includes forming a bottom electrode, forming a ferroelectric layer over the bottom electrode, forming a seed layer over the ferroelectric layer, forming a channel layer on the seed layer, and forming source/drain electrodes at sidewalls of the channel layer. The seed layer is formed by using a physical vapor deposition (PVD) process, and the seed layer has a spinel structure.

According to some embodiments, a field-effect transistor device at least includes a bottom electrode, a ferroelectric layer, a quasi-crystalline seed layer, a channel layer, and source/drain electrodes. The ferroelectric layer is disposed over the bottom electrode. The quasi-crystalline seed layer is disposed over the ferroelectric layer. The channel layer is formed on the quasi-crystalline seed layer, wherein the channel layer has a spinel structure. The source/drain electrodes are disposed at two sides of the channel layer over the ferroelectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a field-effect transistor device, comprising:
forming a bottom electrode;
forming a ferroelectric layer over the bottom electrode;
forming a quasi-crystalline seed layer over the ferroelectric layer;
forming a channel layer on the quasi-crystalline seed layer, wherein the channel layer has a spinel structure; and
forming source/drain electrodes at sidewalls of the channel layer.

2. The method of manufacturing a field-effect transistor device of claim 1, wherein the channel layer comprises a plurality of first sublayers and a plurality of second sublayers alternately stacked.

3. The method of manufacturing a field-effect transistor device of claim 2, wherein the channel layer is formed by an atomic layer deposition (ALD) process, and the ALD process comprises introducing a first precursor mixture for forming the plurality of first sublayers; and introducing a second precursor mixture for forming the plurality of second sublayers, wherein the second precursor mixture comprises same precursors as the first precursor mixture.

4. The method of manufacturing a field-effect transistor device of claim 3, wherein the ALD process further comprises introducing a third precursor between introducing the first precursor mixture and introducing the second precursor mixture, and the third precursor comprises an anion in the spinel structure.

5. The method of manufacturing a field-effect transistor device of claim 1, further comprising forming a final sublayer on the channel layer using a physical vapor deposition (PVD) process or a pulsed laser deposition (PLD) process.

6. The method of manufacturing a field-effect transistor device of claim 5, wherein the final sublayer has same composition as the quasi-crystalline seed layer.

7. A method of manufacturing a field-effect transistor device, comprising:
forming a bottom electrode;
forming a ferroelectric layer over the bottom electrode;
forming a seed layer over the ferroelectric layer using a physical vapor deposition (PVD) process, wherein the seed layer has a spinel structure;
forming a channel layer on the seed layer; and
forming source/drain electrodes at sidewalls of the channel layer.

8. The method of manufacturing a field-effect transistor device of claim 7, wherein the seed layer comprises a plurality of first atomic layers and a plurality of second atomic layers alternately stacked.

9. The method of manufacturing a field-effect transistor device of claim 8, wherein the PVD process comprises performing a deposition step for forming the plurality of first atomic layers; and performing a co-sputtering for forming the plurality of second atomic layers.

10. The method of manufacturing a field-effect transistor device of claim 8, wherein the PVD process comprises performing a first deposition step for forming the plurality of first atomic layers; and performing a second deposition step using a mixing target for forming the plurality of second atomic layers.

11. The method of manufacturing a field-effect transistor device of claim 8, wherein the PVD process further comprises a pre-deposition thermal treatment between each step of forming the plurality of first atomic layers and each step of forming the plurality of second atomic layers.

12. The method of manufacturing a field-effect transistor device of claim 11, wherein a time of the pre-deposition thermal treatment is less than 30 seconds, and a temperature of the pre-deposition thermal treatment is in a range of 150° C.-400° C.

13. The method of manufacturing a field-effect transistor device of claim 7, wherein the channel layer has a quasi-spinel structure.

14. A field-effect transistor device, comprising:
a bottom electrode;
a ferroelectric layer formed over the bottom electrode;
a quasi-crystalline seed layer formed over the ferroelectric layer;
a channel layer formed on the quasi-crystalline seed layer, wherein the channel layer has a spinel structure; and
source/drain electrodes, disposed at two sides of the channel layer over the ferroelectric layer.

15. The field-effect transistor device of claim 14, wherein the seed layer comprises a plurality of first atomic layers and a plurality of second atomic layers alternately stacked.

16. The field-effect transistor device of claim 14, wherein a thickness of the seed layer is in a range of 1-50 nm.

17. The field-effect transistor device of claim 14, wherein a material composition of the seed layer comprises ZnGa₂O₄, MgO, Al₂O₃, MgAlOₓ, or MgZn₂O₄.

18. The field-effect transistor device of claim 14, wherein the channel layer comprises a plurality of first sublayers and a plurality of second sublayers alternately stacked.

19. The field-effect transistor device of claim 14, wherein the source/drain electrodes are in direct contact with the two sides of the channel layer.

20. The field-effect transistor device of claim 14, further comprising a first high-k dielectric layer disposed between the bottom electrode and the ferroelectric layer; and a second high-k dielectric layer disposed between the quasi-crystalline seed layer and the ferroelectric layer.
